(19) United States
(12) Patent Application Publication
(10) Pub. No.: US 2012/0235246 A1
(43) Pub. Date: Sep. 20, 2012

(54) SEMICONDUCTOR DEVICE

(75) Inventors: Kazuhide ABE, Kanagawa (JP); Tadahiro Sasaki, Tokyo (JP); Kazuhiko Itaya, Kanagawa (JP)

(73) Assignee: Kabushiki Kaisha Toshiba, Minato-ku (JP)

(21) Appl. No.: 13/425,735

(22) Filed: Mar. 21, 2012

Related U.S. Application Data
(63) Continuation of application No. PCT/JP2009/004959, filed on Sep. 29, 2009.

(51) Int. Cl. H01L 27/088

(52) U.S. Cl. 257/390; 257/E27.06

(57) ABSTRACT

One embodiment of a semiconductor device provided with a semiconductor substrate, a device region formed on the semiconductor substrate, a device isolation region, which encloses the device region, a plurality of first gate electrodes arranged so as to be parallel to each other on the device region and electrically connected to each other, and a plurality of second gate electrodes arranged so as to be parallel to a plurality of first gate electrodes on the device region and electrically connected to each other, wherein the first gate electrode is arranged so as to be interposed between the second gate electrodes, a gate width of the first gate electrode is smaller than the gate width of the second gate electrode, and a DC bias voltage higher than that of the second gate electrode is applied to the first gate electrode.

### CROSS-REFERENCE TO RELATED APPLICATION

This application is continuation application based upon the International Application PCT/JP2009/004959, the International Filing Date of which is Sep. 29, 2009, the entire content of which is incorporated herein by reference.

### FIELD

Embodiments described herein relate generally to a semiconductor device.

### BACKGROUND

Recently, a modulation method referred to as an orthogonal frequency divisional multiplexing (hereinafter referred to as OFDM) method is widely adopted in a field of wireless communication. The OFDM method is characterized in that this may transmit and receive an amount of information larger than that of a conventional method and that this is insusceptible to an effect by a multipath and the like.

A signal modulated by the OFDM method has a characteristic that on-peak power relative to average power (a peak-to-average power ratio: PAPR) is large. In order to emit the modulated signal from an antenna as an electromagnetic wave, it is required to electrically amplify the modulated signal. Especially, when the PAPR is large as in the OFDM method, it becomes difficult to realize input-output linearity and high power efficiency by an amplifier. An amplifying circuit in which the amplifier that performs class-A operation and the amplifier that performs class-B operation are connected in parallel in order to solve the problem has been proposed.

On the other hand, reduction in cost of a portable wireless terminal is required, and a method of applying a CMOS transistor to a high-frequency power amplifier of a transmitting unit is suggested. Since the maximum working voltage of CMOS transistors is low, it is required to arrange a plurality of MOS transistors on the same substrate and connect the transistors in parallel in order to obtain a large output current.

A typical layout configuration to arrange a plurality of gate electrodes on the same device region is referred to as a multi-fingered layout structure. In the multi-fingered layout structure, a plurality of gate electrodes placed so as to be parallel to each other and electrically connected to each other are located on the same device region.

In addition, a power amplifier having the multi-fingered layout structure in which the gate electrodes of the transistors of the different amplifiers are arranged on the same device region has been proposed.

### BRIEF DESCRIPTION OF THE DRAWINGS

FIG. 1A, 1B is a schematic view of a configuration of a semiconductor device of the first embodiment.

FIG. 2 is the schema showing equivalent circuit for the semiconductor device of the first embodiment.

FIG. 3 is a diagram showing the relation between input power and output power for the circuit illustrated in FIG. 2.

FIG. 4 is an illustrative diagram of an action when an amplifying circuit in FIG. 2 is applied to an OFDM modulated signal.

FIG. 5 is a comparison of the operation between a class-A amplifier and a class-B amplifier.

FIG. 6A, 6B is a view illustrating anomalous characteristics of the semiconductor device having a multi-fingered layout structure.

FIG. 7A, 7B is a schematic view of a configuration of the semiconductor device of a second embodiment.

FIG. 8A, 8B is a schematic view of a configuration of the semiconductor device of the third embodiment.

### DETAILED DESCRIPTION

A semiconductor device of one embodiment is provided with a semiconductor substrate, a device region formed on the semiconductor substrate, a device isolation region, which encloses the device region, a plurality of first gate electrodes arranged so as to be parallel to each other on the device region and electrically connected to each other, and a plurality of second gate electrodes arranged so as to be parallel to a plurality of first gate electrodes on the device region and electrically connected to each other, wherein the first gate electrode is arranged so as to be interposed between the second gate electrodes, a gate width of the first gate electrode is smaller than the gate width of the second gate electrode, and a DC bias voltage higher than that of the second gate electrode is applied to the first gate electrode.

Embodiments are hereinafter described with reference to the drawings.

### First Embodiment

A semiconductor device of this embodiment is provided with a semiconductor substrate, a device region formed on the semiconductor substrate, a device isolation region, which encloses the device region, a plurality of first gate electrodes arranged on the device region so as to be parallel to each other and electrically connected to each other, and a plurality of second gate electrodes arranged on the device region so as to be parallel to a plurality of first gate electrodes and electrically connected to each other. The first gate electrode is arranged so as to be interposed between the second gate electrodes. A gate width of the first gate electrode is smaller than the gate width of the second gate electrode. It is configured such that a DC bias voltage higher than that of the second gate electrode is applied to the first gate electrode.

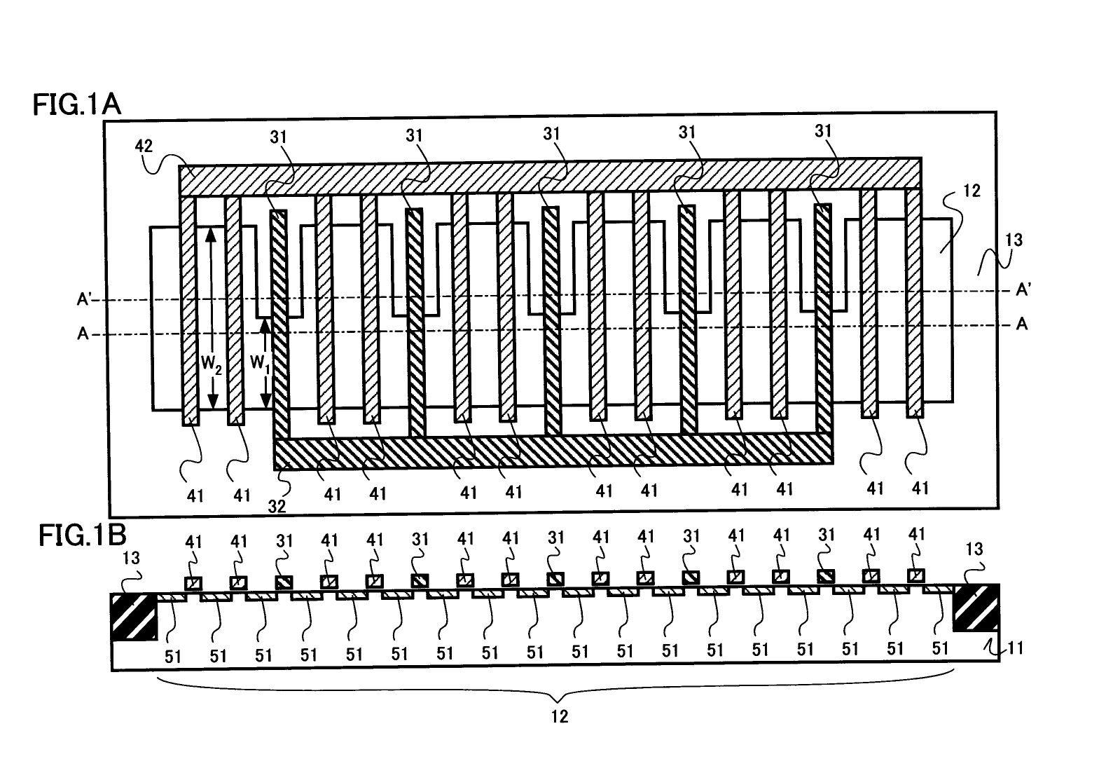

FIG. 1A, 1B is a schematic view of a configuration of the semiconductor device of this embodiment. FIG. 1A is a plan view and FIG. 1B is a cross-sectional view taken along a line A-A in FIG. 1A.

The semiconductor device of this embodiment is a high-frequency power amplifier. The high-frequency power amplifier is used in a transmitting unit of a portable wireless terminal, for example.

According to the configuration of this embodiment, it is possible to realize a compact high-frequency power amplifier by integrally arranging transistors used in two amplifiers operating with different bias voltages on the same device region. In addition, by diffused distribution of a heat source, it is possible to inhibit generation of a high-temperature portion in the device and realize the high-frequency power amplifier capable of performing stable operation. Further, by taking measures against unstable operation inherent in a multi-fingered layout structure, it is possible to realize the high-frequency power amplifier capable of performing the stable operation.

As illustrated in FIGS. 1A and 1B, a device region 12 is formed on a semiconductor substrate 11 of silicon, for example. The device region 12 is enclosed by a device isolation region 13 formed of an insulating film.

In addition, 5 first gate electrodes 31 and 12 second gate electrodes 41 are formed on the device region 12 through a gate insulating film (not illustrated). A part of the gate electrodes 31 and 41 is extended on the adjacent device isolation region 13.

A plurality of the first gate electrodes 31 are arranged so as to be parallel to each other. Also, they are electrically connected to each other through a first common electrode 32. A plurality of the second gate electrodes 41 are arranged so as to be parallel to each other and parallel to a plurality of first gate electrodes 31. Each of the first gate electrodes 31 is arranged so as to be interposed between the second gate electrodes 41. A plurality of second gate electrodes 41 are electrically connected to each other through a second common electrode 42.

Diffusion layers 51 for source and drain are formed on a surface portion of the device region 12. The portions between the adjacent diffusion layers 51 are channel regions. In this manner, the semiconductor device of this embodiment has the multi-fingered layout structure.

Lengths of the first gate electrodes 31 and the second gate electrodes 41 in the direction orthogonal to the channel length direction are equivalent to each other. Also, gate lengths (dimensions parallel to the channel length direction) of the first gate electrodes 31 and the second gate electrodes 41 are equivalent to each other. All of 17 gate electrodes including the first gate electrodes 31 and the second gate electrodes 41 are arranged so as to be parallel to each other at the same pitch.

Since the gate electrodes are periodically arranged in this manner, high-accuracy precise microfabrication can be easily achievable in a photolithography process and an etching process. Therefore, it is possible to achieve uniform gate dimensions and obtain the semiconductor device having stable and reproducible characteristics.

The gate width (the dimension in a channel width direction: W₁ in FIG. 1A) of the first gate electrode 31 is smaller than the gate width (W₂ in FIG. 1A) of the second gate electrode 41. Herein, the gate width is intended to mean a length corresponding to a channel width of the transistor. In other words, this is intended to mean a dimension in the direction of extension of the gate electrodes 31 and 41 in a region in which the gate electrodes 31 and 41 intersect with the device region 12.

In addition, the semiconductor device of this embodiment is configured such that the DC bias voltage higher than that of the second gate electrode 41 is applied to the first gate electrode 31.

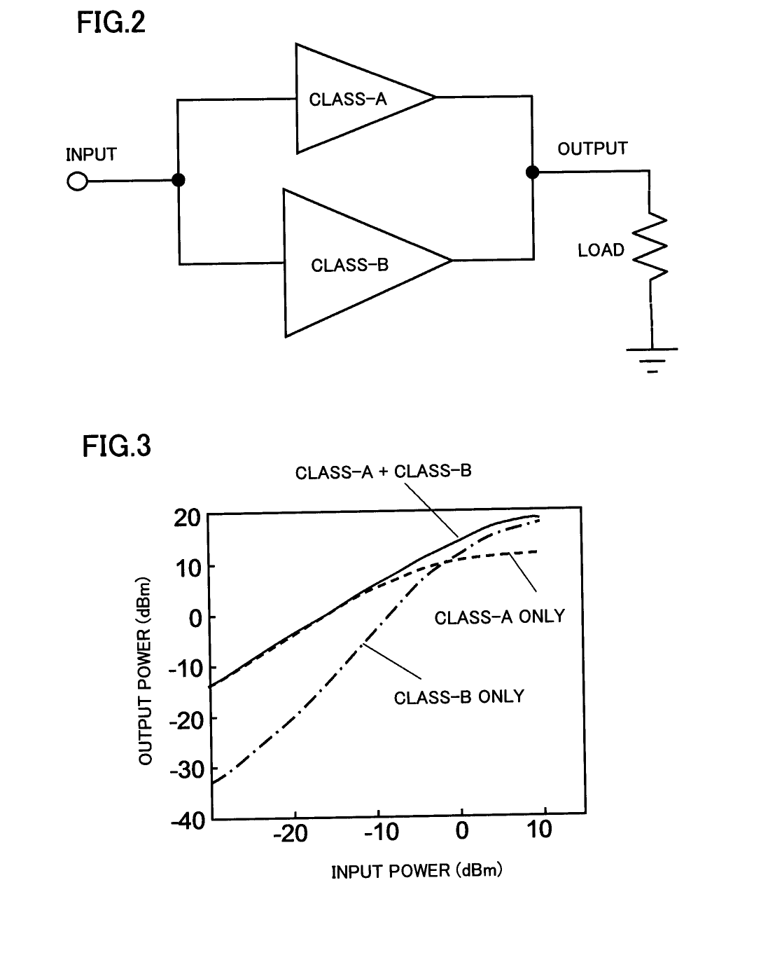

FIG. 2 is a view illustrating a equivalent circuit of the semiconductor device of this embodiment. The circuit is composed of parallel connection of two amplifying circuits of which input sides and output sides are connected in common. Out of the two amplifying circuits, one is an amplifier that performs class-A operation (hereinafter, referred to as a class-A amplifier), and the other is the amplifier that performs class-B operation (hereinafter, referred to as a class-B amplifier).

The same modulated signal is input to the two amplifiers. Output signals of the amplifiers are synthesized to be supplied to a load. The load is an antenna, for example, in a case of a wireless communication system.

Herein, the first gate electrode 31 in FIGS. 1A and 1B corresponds to a gate electrode of the transistor used in the class-A amplifier and the second gate electrode 41 corresponds to the gate electrode of the transistor used in the class-B amplifier.

FIG. 3 is a view illustrating input power vs. output power characteristics of the circuit in FIG. 2. It is known that, by connecting the class-A amplifier and the class-B amplifier in parallel and designing the transistor used in each of the amplifiers using an appropriate parameter, the characteristics indicated by a solid line in FIG. 3 can be obtained as a synthesized output signal power.

When the power of the input signal is small, the power of the output signal is substantially equivalent to that of the class-A amplifier. That is to say, the output signal proportional to the input signal may be obtained and high linearity between the input signal and the output signal is achievable. Therefore, the linearity is much better than that in a case in which it is composed only of the class-B amplifier.

On the other hand, although the output of the class-A amplifier is gradually saturated as the power of the input signal becomes larger, the output of the class-B amplifier becomes larger in place of this, so that the synthesized output is larger than that in a case in which it is composed only of the class-A amplifier.

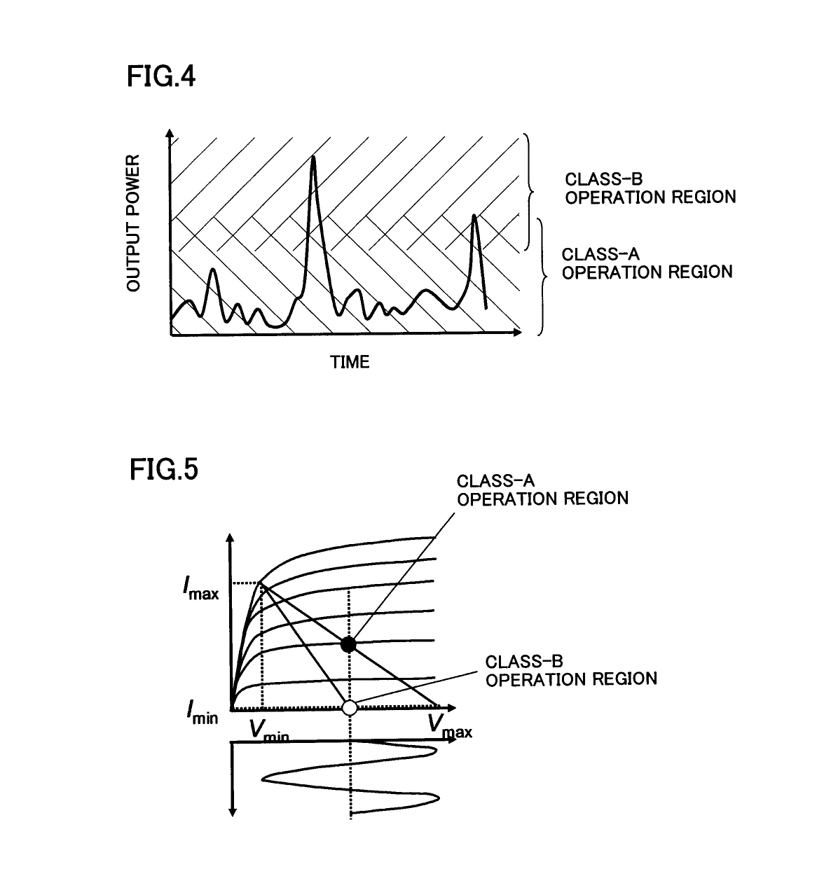

FIG. 4 is an illustrative diagram of the operation when the amplifying circuit in FIG. 2 is applied to an OFDM modulated signal. FIG. 4 illustrates an example of a waveform of the signal modulated by an OFDM scheme. The OFDM modulated signal is characterized in that Peak to Average Ratio (PAPR) is large as described above. This means that the power amplifier handles a low power signal in most of operating time.

In the amplifying circuit in FIG. 2, the class-A amplifier operates to perform linear amplification when the power of the input signal is low as illustrated in FIG. 4. On the other hand, in the case of the OFDM modulated signal, a high power signal is sometimes input. Although the class-A amplifier is saturated when the high power signal is input, the class-B amplifier operates in place of this, so that it is possible to amplify the signal to a higher power.

FIG. 5 is a chart to compare the characteristics of the class-A amplifier and the class-B amplifier. The view in FIG. 5 illustrates drain current-drain voltage characteristics (Id-Vd characteristics) at different gate voltages. Load lines and operation points of the class-A amplifier and the class-B amplifier are also illustrated.

In the class-A amplifier, it is required to always apply a constant DC bias voltage to the gate electrode and thereby apply a constant DC bias current between the source and the drain. Therefore, although the linear operation between the input and the output is achievable, power efficiency is low because the power is steadily consumed. On the other hand, in the class-B amplifier, whereas the bias current is approximately eliminated, steady power consumption is low and the power efficiency is excellent, the linear operation cannot be expected.

As described above, the first gate electrode 31 in FIGS. 1A and 1B corresponds to the gate electrode of the transistor used in the class-A amplifier and the second gate electrode 41 corresponds to the gate electrode of the transistor used in the class-B amplifier. Predetermined potential is applied to the first common electrode 32 for the class-A operation. Also, predetermined potential is applied to the second common electrode 42 for the class-B operation. Herein, it is configured such that the DC bias voltage higher than that of the second common electrode 42 is applied to the first common electrode 32 for the class-A operation. That is to say, it is configured such that the DC bias voltage higher than that of the second gate electrode 41 is applied to the first gate electrode 31.

Then, the predetermined potential is applied to the drain of the transistor used in the class-A amplifier for the class-A operation. Also, the predetermined potential is applied to the drain of the transistor used in the class-B amplifier for the class-B operation.

According to the high-frequency power amplifier of this embodiment, the transistor used in the class-A amplifier and the transistor used in the class-B amplifier are not separately formed in different device regions but formed in the same device region. Therefore, an entire layout area may be made smaller, so that a small and low-cost high-frequency power amplifier may be realized.

Also, the layout is such that the gate electrode of the transistor of the class-B amplifier is interposed between the gate electrodes of the transistor of the class-A amplifier with large power consumption and a large amount of heat generation for the bias voltage/current steadily applied. By this layout, it becomes possible to distribute the heat sources, thereby inhibiting local concentration of the heat generation. Therefore, variation of the transistor characteristics by local heat generation can be inhibited and the high-frequency power amplifier capable of performing the stable and reproducible operation may be realized.

The high-frequency power amplifier of this embodiment is capable of further inhibiting the local increase in the amount of heat by decreasing the gate width of the first gate electrode 31 of the transistor of the class-A amplifier than the gate width of the second gate electrode 41 of the transistor of the class-B amplifier in which a large output is required.

In addition, according to the layout of this embodiment, it also becomes possible to inhibit anomalous operation generated in the semiconductor device having the multi-fingered layout structure, for example, negative resistance. The anomalous characteristics generated in the semiconductor device having the multi-fingered layout structure are considered to be attributed to an acoustic standing wave generated in the device region.

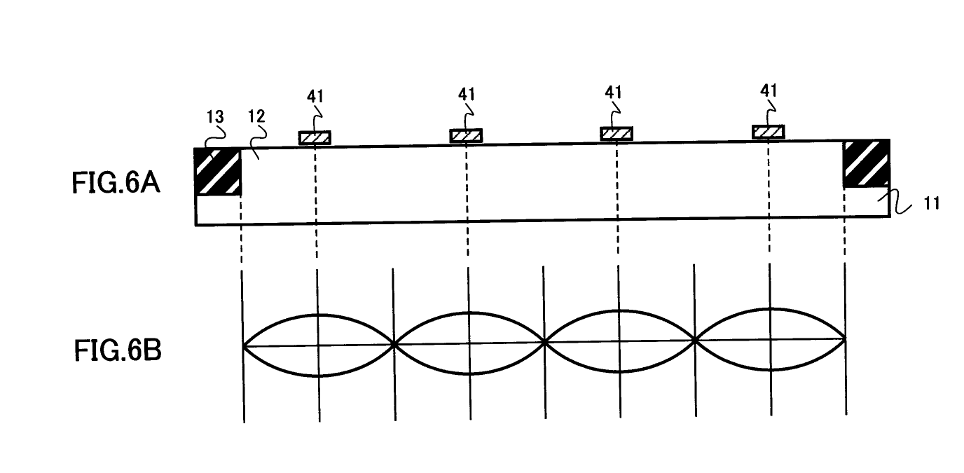

FIG. 6A, 6B is a view illustrating the anomalous characteristics of the semiconductor device having the multi-fingered layout structure. Hereinafter, the effect of this embodiment is described with reference to FIG. 6A, 6B. FIG. 6A is a cross-sectional view of the semiconductor device and FIG. 6B is a view illustrating the acoustic standing wave.

In the semiconductor device having the multi-fingered layout structure, a planar shape of the device region is rectangular in general. That is to say, a pair of opposed sides of the device region are parallel to each other. A plurality of gate electrodes are arranged at the same pitch (with the same period).

When the transistor operates, a channel is formed under the gate electrode and a conduction carrier is accelerated by a voltage Vds applied between the source and the drain. As the voltage Vds between the source and the drain is higher, the velocity of the carriers becomes higher, and the kinetic energy of the carriers becomes higher. When the carrier having high kinetic energy collides with a crystal lattice of the semiconductor, a part of the kinetic energy is converted to energy of lattice vibration.

The energy of the lattice vibration is distributed to various wavelengths, various frequencies, and various energies. The lattice vibration also includes the acoustic wave having the wavelength, which is synchronized to the period of arrangement of the gate electrode.

The acoustic wave, which propagates in the crystal, has a tendency of propagating farther if the wavelength is longer. Also, since different constituent materials are used in the device region and the device isolation region, acoustic impedance is different. Therefore, the acoustic wave is reflected on a boundary between the device region and the device isolation region. Therefore, when the distance between the both sides opposed to each other of the device region is equal to integer times of the wavelength of the acoustic wave, the standing wave as illustrated in FIG. 6B can be generated.

When the wavelength of the acoustic standing wave and the period of arrangement of the gate electrodes coincide with each other, in the channel region of the transistor, the amplitude of the lattice vibration periodically changes. Therefore, collision probability and collision impact of the carriers, which are conducted in the channel, against the crystal lattice also periodically change. As a result, strength of the acoustic standing wave is further enhanced. That is to say, a positive feedback mechanism works and the standing wave continues to exist.

The collision of the conduction carrier against the crystal lattice generates a new electron-hole pair by impact ionization. A part of the generated electron-hole pairs changes substrate potential, and as a result, a threshold voltage of the transistor changes. When the number of carriers, which are conducted in the channel, decreases by the change in the threshold voltage, the negative resistance and the like are observed.

It is known that a substrate current Isub generated by impact ionization is given by a following equation.

$${I}_{sub} = ( {α}_{1} + \frac{{α}_{0}}{{L}_{eff}} ) ( {V}_{ds} - {V}_{deff} ) exp ( - \frac{{β}_{0}}{{V}_{ds} - {V}_{deff}} ) {I}_{dsa} \qquad [ Equation 1 ]$$

According to this equation, when the DC bias current is small, especially when a DC drain current is negligible, the substrate current by the impact ionization is not generated and it is stable. Therefore, a rate of the impact ionization of the transistor of the amplifier working in class-B operation is smaller than that of the transistor of the amplifier working in class-A operation. Therefore, it may be said that the transistor of the class-A amplifier amplifies the vibration of crystal lattice and this contributes to generation of the acoustic standing wave.

In this embodiment, the layout is such that the gate electrode 41 of the transistor of the class-B amplifier is interposed between the gate electrodes 31 of the transistor of the class-A amplifier. According to this layout, the distance between the gate electrodes 31 of the transistor of the class-A amplifier is increased and mutual interference of the acoustic waves generated under the gate electrode is reduced.

Further, as is clear from FIG. 1A, the portions of the device region 12 between the gate electrodes 41 of the transistor of the class-B amplifier are not fully continuous, but the region is partly interposed by the device isolation region 13. For example, the device isolation region 13 is present on a line A′-A′ in FIG. 1A.

Therefore, the acoustic wave generated in the gate electrode 41 of the transistor of the class-B amplifier is reflected on the boundary between the device region 12 and the device isolation region 13. Therefore, it is possible to inhibit the generation and amplification of the standing wave using an entire width of the device region as illustrated in FIG. 6B.

In this manner, by improving the layouts of the transistor of the class-A amplifier and the transistor of the class-B amplifier, the positive feedback mechanism of the acoustic wave is inhibited from being activated, and the standing wave is inhibited from being continuously present. Therefore, the high-frequency power amplifier capable of performing the stable operation may be realized by taking measures against an unstable operation inherent in the multi-fingered layout structure.

Furthermore, it is well known in the semiconductor devices having the multi-fingered layout structure that the output signal of power amplifier strongly depends on the amplitude of preceding input signal, a so-called memory effect. It is expected in this embodiment that variation in heat generation by the preceding signal amplitude is inhibited, and generation of the memory effect may thereby be inhibited by distributing the gate electrodes of the transistor of the class-A amplifier, which consume larger electric power and generate larger amount of heat.

### Second Embodiment

The semiconductor device of this embodiment is characterized in that, as for the two adjacent first gate electrodes, the first gate electrodes are arranged such that, when parallel shift of the region in which the first gate electrode intersects with the device region is performed in a direction perpendicular to the direction of extension of the first gate electrode, there is a region, which is not overlapped, at least on a part thereof. This is similar to that of the first embodiment except the arrangement of the first gate electrodes. Therefore, the contents overlapping with those of the first embodiment will not be repeated.

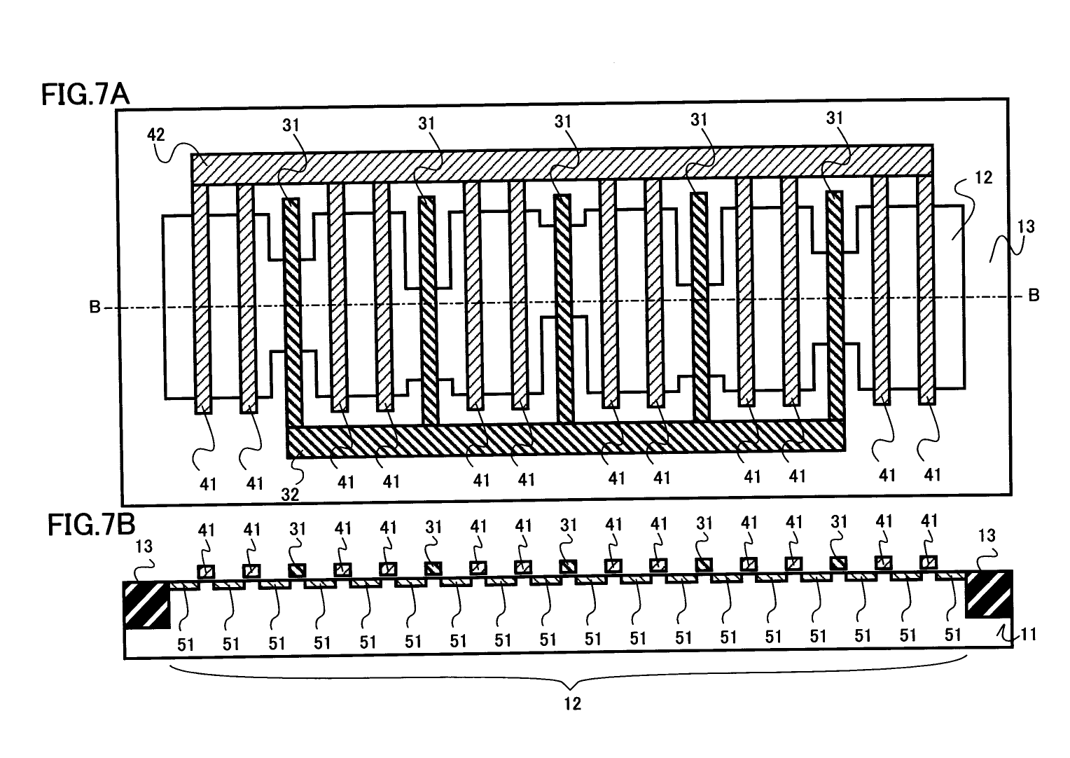

FIG. 7A, 7B is a schematic view of the configuration of the semiconductor device of this embodiment. FIG. 7A is a plan view and FIG. 7B is a cross-sectional view taken along a line B-B in FIG. 7A.

As for the two adjacent first gate electrodes 31 with the second gate electrode 41 interposed therebetween, the first gate electrodes 31 are arranged such that, when the parallel shift of the region in which the first gate electrode 31 intersects with the device region 12 is performed in the direction perpendicular to the direction of extension of the first gate electrode 31, there is the region, which is not overlapped, at least on a part thereof. In other words, arrangement is such that, when the channel region of an optional first gate electrode 31 is virtually moved in a transverse direction on a plane of paper in FIG. 7A, 7B, the moved channel region and at least a part of the channel region under the adjacent first gate electrode 31 are not overlapped with each other.

By this layout, the acoustic wave generated in the gate electrode 31 of the transistor of the class-A amplifier to propagate in the direction perpendicular to the direction of extension of the gate electrode (channel length direction) is reflected on the boundary between the device region 12 and the device isolation region 13. Therefore, it is possible to inhibit the generation and the amplification of the standing wave using an entire width of the device region as illustrated in FIG. 68.

In this embodiment, as for the transistor of the class-A amplifier, which generates the acoustic wave larger than that of the transistor of the class-B amplifier and contributes to the generation of the acoustic standing wave, propagation of the acoustic wave, which travels in the direction perpendicular to the direction of extension of the gate electrode (channel length direction) is inhibited. Therefore, it is possible to realize the high-frequency power amplifier capable of performing more stable operation than that of the first embodiment.

### Third Embodiment

The semiconductor device of this embodiment is characterized in that, as for the two adjacent first gate electrodes, the first gate electrodes are arranged such that, when the parallel shift of the region in which the first gate electrode intersects with the device region is performed in the direction perpendicular to the direction of extension of the first gate electrode, there is no overlapped region. This is similar to that of the first and second embodiments except the arrangement of the first gate electrodes. Therefore, the contents overlapping with those of the first and second embodiments will not be repeated.

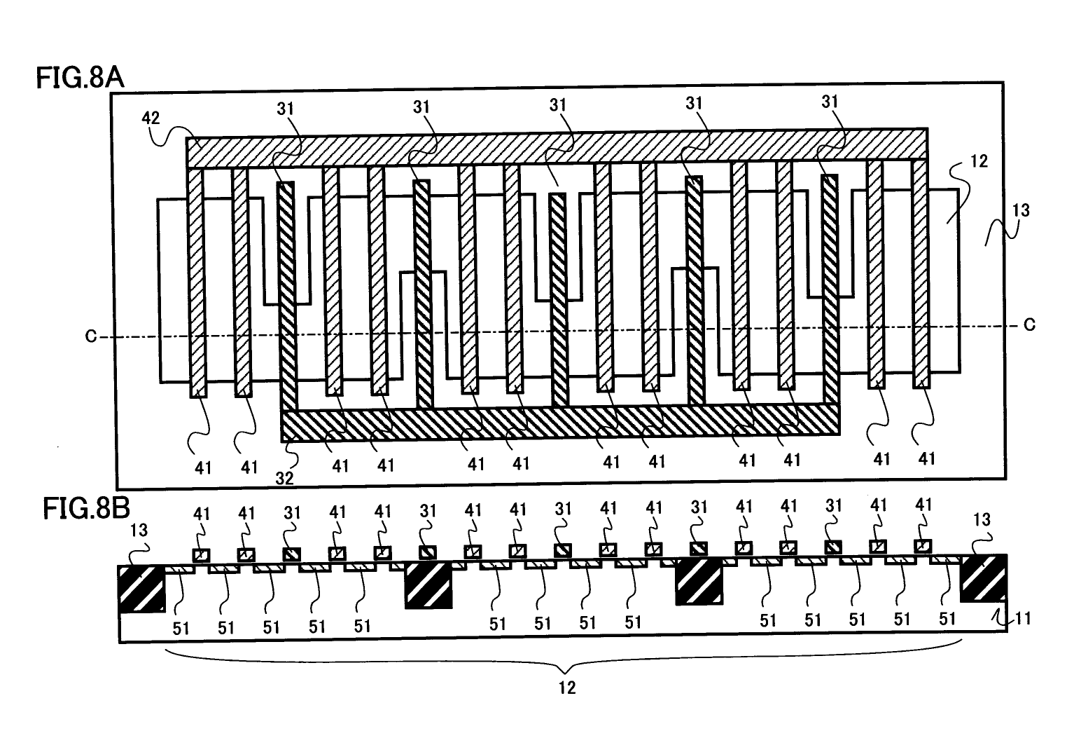

FIG. 8A, 8B is a schematic view of the configuration of the semiconductor device of this embodiment. FIG. 8A is a plan view and FIG. 8B is a cross-sectional view taken along a line C-C in FIG. 8A.

As for the two adjacent first gate electrodes 31 with the second gate electrode 41 interposed therebetween, the first gate electrodes 31 are arranged such that, when the parallel shift of the region in which the first gate electrode 31 intersects with the device region 12 is performed in the direction perpendicular to the direction of extension of the first gate electrode 31, there is no overlapped region. In other words, the arrangement is such that, when the channel region of an optional first gate electrode 31 is virtually moved in the transverse direction on a plane of paper in FIG. 8A, 8B, the moved channel region is not at all overlapped with the channel region under the adjacent first gate electrode 31.

By this layout, the acoustic wave generated in the gate electrode 31 of the transistor of the class-A amplifier to propagate in the direction perpendicular to the direction of extension of the gate electrode (channel length direction) is reflected on the boundary between the device region 12 and the device isolation region 13 before this reaches the gate electrode 31 of the transistor of the adjacent class-A amplifier. Therefore, as for the class-A amplifier, it is possible to completely inhibit the generation and the amplification of the standing wave using the entire width of the device region as illustrated in FIG. 6B.

In this embodiment, as for the transistor of the class-A amplifier, which generates the acoustic wave larger than that of the transistor of the class-B amplifier and contributes to the generation of the acoustic standing wave, the propagation of the acoustic wave, which travels in the direction perpendicular to the direction of extension of the gate electrode (channel length direction) is further inhibited. Therefore, it is possible to realize the high-frequency power amplifier capable of performing more stable operation than that of the first and second embodiments.

While certain embodiments have been described, these embodiments have been presented by way of example only, and are not intended to limit the scope of the inventions. Indeed, semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

For example, an example in which a plurality of first gate electrodes with the same gate width W₁ and a plurality of the second gate electrodes with the same gate width W₂ are arranged is described in the first to third embodiments, it is not necessarily required to use those of the same gate width when a relationship of W₁<W₂ is satisfied.

Although an example in which the two second gate electrodes are arranged between the adjacent first gate electrodes is illustrated in the first to third embodiments, the number is not necessarily required to be two. Also, it is not necessarily required that the gate electrodes of the same number are arranged.

Although the high-frequency power amplifier is described as an example of the semiconductor device, the present invention may also be applied to another semiconductor device having the multi-fingered layout structure, for example, a constant current source of an analog circuit.

The present invention may also be applied to an n-type MOS transistor (n-type MIS transistor) of which carrier is the electron and a p-type MOS transistor (p-type MIS transistor) of which carrier is the hole. This may also be applied to a laterally diffused MOS (LDMOS).

What is claimed is:

1. A semiconductor device, comprising:
a semiconductor substrate;
a device region formed on the semiconductor substrate;
a device isolation region, which encloses the device region;
a plurality of first gate electrodes arranged so as to be parallel to each other on the device region and electrically connected to each other; and
a plurality of second gate electrodes arranged so as to be parallel to the plurality of first gate electrodes on the device region and electrically connected to each other,
wherein each of the first gate electrodes is arranged so as to be interposed between the second gate electrodes, a gate width of the first gate electrode is smaller than the gate width of each of the second gate electrodes, and a DC bias voltage higher than the DC bias voltage of the second gate electrode is applied to the first gate electrode.

2. The device according to claim 1, wherein, as for two adjacent first gate electrodes, the first gate electrodes are arranged such that, when parallel shift of a region in which the first gate electrode intersects with the device region is performed in a direction perpendicular to a direction of extension of the first gate electrode, there is a region, which is not overlapped, at least on a part of the region.

3. The device according to claim 2, wherein, as for the two adjacent first gate electrodes, the first gate electrodes are arranged such that, when the parallel shift of the region in which the first gate electrode intersects with the device region is performed in the direction perpendicular to the direction of extension of the first gate electrode, there is no overlapped region.
